(19) United States
(12) Patent Application Publication
(10) Pub. No.: US 2024/0198418 A1
(43) Pub. Date: Jun. 20, 2024

(54) COPPER PASTE FOR PRINTING CAPILLARY STRUCTURE AND PREPARATION METHOD THEREOF

(71) Applicant: AAC Technologies (Nanjing) Co., Ltd., Nanjing (CN)

(72) Inventors: Bo Zhang, Nanjing (CN); Guochuang Huang, Nanjing (CN); Hezhi Wang, Nanjing (CN)

(21) Appl. No.: 18/338,378

(22) Filed: Jun. 21, 2023

Related U.S. Application Data
(63) Continuation of application No. PCT/CN2022/144334, filed on Dec. 30, 2022.

(30) Foreign Application Priority Data
Dec. 20, 2022 (CN) 202211646215.1

(51) Int. Cl. B22F 1/10; B22F 1/052

(52) U.S. Cl. CPC B22F 1/10; B22F 1/052; B22F 2301/10; B22F 2304/058; B22F 2304/10

(57) ABSTRACT

The present invention discloses a copper paste for printing a capillary structure and a preparation method thereof. The copper paste consists of copper powder, a high molecular polymer, a solvent, a binder, a dispersant, a leveling agent, a tackifier and an antioxidant. Through the limitation on the copper powder and the high molecular polymer in the copper paste of the present invention, the prepared copper paste can be applied to a carrier of a vapor chamber by blade coating or screen printing, and then used as a wick after binder removal and sintering in hydrogen or hydrogen-nitrogen mixed gas, so as to reduce device investment and cost; and the thickness of the wick can be accurately controlled to be 10-100 μm, the structural strength is higher, the water absorption performance and the heat transfer performance are better, and the demand for miniaturization of electronic products is met.

### TECHNICAL FIELD

The present invention relates to the technical field of vapor chambers, in particular to a copper paste for printing a capillary structure and a preparation method thereof.

### BACKGROUND

The high-frequency and high-speed development of electronic components and integrated circuit technology will lead to the generation of a large amount of heat by electronic components during operation. For example, the heat flux of a computer CPU during operation has reached 60-100 W/cm², and even as high as 103 W/cm² in a semiconductor laser device.

The working reliability of an electronic device is extremely sensitive to temperature, and every 1° C. increase in the temperature of its components at the level of 70-80° C. will reduce the reliability by 5%, which indicates that high heat flux poses a great threat to the normal working reliability of components, so heat dissipation is key to the miniaturization of electronic products. In order to ensure normal operation of the electronic component, a cooler is usually installed on the electronic component to dissipate heat. At present, the mainstream design is to install a vapor chamber with good thermal conductivity between the cooler and the electronic component. The role of the vapor chamber is to evenly distribute the heat of the electronic component first, and then dissipate the heat through the cooler.

The vapor chamber is a heat-conducting component which realizes rapid heat transfer by the phase change of its internal working fluid. The vapor chamber mainly comprises upper and lower cover plates or metal pipes, a sealing head, a wick and a heat transfer working medium. Here, a capillary structure of the wick has a direct influence on the performance of the vapor chamber, and the capillary structure requires a strong capillary force and small water flow resistance.

There are many types of wicks with a capillary structure in the vapor chamber, such as foamy copper, copper mesh, composite copper mesh and etched capillary structure. However, due to structural and space constraints, the vapor chamber needs to be thinner.

Due to the miniaturization development trend of electronic products, components constituting the electronic products are required to be smaller and thinner, which makes the requirement for the thickness of the vapor chamber more demanding. For example, ultra-thin vapor chambers with a thickness of less than 280 μm came into being under such requirement, which need a thinner wick while improving the heat transfer performance. However, an existing vapor chamber has a thick wick and poor water absorption and heat transfer performance, which cannot meet the demand for miniaturization of electronic products.

Therefore, it is necessary to provide a copper paste for printing a capillary structure to solve the above technical problems.

### SUMMARY

The purpose of the present invention is to provide a copper paste for printing a capillary structure to solve the problem that an existing vapor chamber has a thick wick and poor water absorption and heat transfer performance, which cannot meet the demand for miniaturization of electronic products.

In a first aspect, the present invention provides a copper paste for printing a capillary structure, which consists of copper powder, a high molecular polymer, a solvent, a binder, a dispersant, a leveling agent, a tackifier and an antioxidant, wherein the particle size of the copper powder ranges from 0.5 μm to 10 μm the particle size of microspheres of the high molecular polymer ranges from 1 μm to 50 μm.

Preferably, the particle size of the microspheres of the high molecular polymer is one or more of 300-1000 meshes, 1000-3000 meshes and 5000-12000 meshes the porosity of the high molecular polymer is 35%-75%.

Preferably, the high molecular polymer is one or more of polymethyl methacrylate, polyisobutyl methacrylate, methyl methacrylate-isobutyl methacrylate copolymer, polyoxymethylene, polyurethane and polystyrene.

Preferably, the solvent is one or more of ethanol, propanol, isopropanol, n-butanol, ethylene glycol, 1,2-propanediol, 1,2-butanediol, 1,4-butanediol and water.

Preferably, the binder is one or more of polyvinylpyrrolidone (PVP), polyvinyl alcohol (PVA), polyvinyl butyral (PVB), polyurethane, hydroxymethyl cellulose and ethyl cellulose.

Preferably, the dispersant is one or more of methyl amyl alcohol, cellulose derivatives, polyacrylamide and polyethylene glycol fatty acid.

Preferably, the leveling agent is one or more of sodium dodecyl sulfate, sodium dodecyl benzene sulfonate, sodium tetradecyl sulfonate, sodium hexadecyl sulfonate, lecithin, triethanolamine, KH550, polyethylene glycol, triethanolamine, Tween 80 and Span 80.

Preferably, the tackifier is high-viscosity resin, and the high-viscosity resin is one or more of natural rubber, styrene-butadiene rubber, neoprene, and C5 and C9 petroleum resins.

Preferably, the antioxidant is one or more of citric acid, phytic acid, vitamins, oxalic acid, ascorbic acid and glucose.

Preferably, the mass ratio of the copper powder to the high molecular polymer is 8-9:1, the mass fraction of the solvent is 1%-70% of a mixture of the copper powder and the high molecular polymer, the mass fraction of the binder is 0.1%-30% of the mixture of the copper powder and the high molecular polymer, the mass fraction of the dispersant is 0.01%-5% of the mixture of the copper powder and the high molecular polymer, the mass fraction of the leveling agent is 0.01%-10% of the mixture of the copper powder and the high molecular polymer, the mass fraction of the tackifier is 0.01%-5% of the mixture of the copper powder and the high molecular polymer, and the mass fraction of the antioxidant is 0.01%-10% of the mixture of the copper powder and the high molecular polymer.

Preferably, the average particle size of the copper powder is 3 μm.

In a second aspect, the present invention provides a preparation method of the copper paste for printing a capillary structure as described above, which comprises the following steps:
uniformly mixing the high molecular polymer with the copper powder according to the composition of the copper paste; and
then adding the solvent, the binder, the dispersant, the leveling agent, the tackifier and the antioxidant and fully stirring them in a mixer for 0.5-6 h.

Compared with the related art, the copper paste for printing a capillary structure in the present invention adopts the copper powder, the high molecular polymer, the solvent, the binder, the dispersant, the leveling agent, the tackifier and the antioxidant as raw constituents, and defines the particle size range of the copper powder and the particle size range of the microspheres of the high molecular polymer, so that the prepared copper paste can be applied to a carrier of a vapor chamber by blade coating or screen printing, and then used as a wick after binder removal and sintering in hydrogen or hydrogen-nitrogen mixed gas, so as to reduce device investment and cost; and the thickness of the wick can be accurately controlled to be 10-100 μm, the structural strength is higher, the water absorption performance and the heat transfer performance are better, and the demand for miniaturization of electronic products is met.

### BRIEF DESCRIPTION OF DRAWINGS

In order to explain the technical solution in the embodiments of the present invention more clearly, the drawings used in the embodiments will be briefly introduced below. Obviously, the drawings in the following description are only for some embodiments of the present invention, and for those of ordinary skill in the art, other drawings can be obtained according to these drawings without creative labor.

FIG. 1 is a flow diagram of a preparation method of a copper paste for printing a capillary structure according to an embodiment of the present invention;

FIG. 2 is a diagram of a surface state of a first wick provided by an embodiment of the present invention; and

FIG. 3 is a diagram of a surface state of a second wick provided by an embodiment of the present invention.

### DETAILED DESCRIPTION OF EMBODIMENTS

The technical schemes in the embodiments of the present invention are clearly and completely described in the following. It is obvious that the described embodiments are only illustrative ones, and are not all possible ones of the present invention. Based on the embodiments of the present invention, all other embodiments obtained by those of ordinary skill in the art without creative labor are within the scope of the present invention.

An embodiment of the present invention provides a copper paste for printing a capillary structure, which consists of copper powder, a high molecular polymer (pore forming substance), a solvent, a binder, a dispersant, a leveling agent, a tackifier and an antioxidant.

Here, the mass ratio of the copper powder to the high molecular polymer is 8-9:1, the mass fraction of the solvent is 1%-70% of a mixture of the copper powder and the high molecular polymer, the mass fraction of the binder is 0.1%-30% of the mixture of the copper powder and the high molecular polymer, the mass fraction of the dispersant is 0.01%-5% of the mixture of the copper powder and the high molecular polymer, the mass fraction of the leveling agent is 0.01%-10% of the mixture of the copper powder and the high molecular polymer, the mass fraction of the tackifier is 0.01%-5% of the mixture of the copper powder and the high molecular polymer, and the mass fraction of the antioxidant is 0.01%-10% of the mixture of the copper powder and the high molecular polymer.

The particle size of the copper powder ranges from 0.5 μm to 10 μm, and the average particle size (D50 or median particle size) is 3 μm. The particle size of microspheres of the high molecular polymer is 1-50 μm.

The particle size of the microspheres of the high molecular polymer is one or more of 300-1000 meshes, 1000-3000 meshes and 5000-12000 meshes. There are ten categories of particle sizes of the microspheres of the high molecular polymer, namely 300 meshes, 500 meshes, 800 meshes, 1000 meshes, 2000 meshes, 3000 meshes, 5000 meshes, 8000 meshes, 10000 meshes and 12000 meshes, wherein 300-1000 meshes is fine powder, 1000-3000 meshes is fine micropowder, and 5000-12000 meshes is superfine powder. The porosity of the high molecular polymer is 35%-75%.

If the particle size of the selected microspheres of the high molecular polymer is 5000-12000 meshes, the prepared copper paste can be applied to copper layers below 20 μm; if the particle size of the selected microspheres of the high molecular polymer is 1000-3000 meshes, the prepared copper paste can be applied to copper layers between 20 μm and 40 μm; and if the particle size of the selected microspheres of the high molecular polymer is 300-1000 meshes, the prepared copper paste can be applied to copper layers between 30 μm and 60 μm. The different particle sizes of the microspheres of the high molecular polymer can be used alone or mixed to change the surface or internal morphology of porous copper layers.

The high molecular polymer is one or more of polymethyl methacrylate, polyisobutyl methacrylate, methyl methacrylate-isobutyl methacrylate copolymer, polyoxymethylene, polyurethane and polystyrene.

The solvent is one or more of ethanol, propanol, isopropanol, n-butanol, ethylene glycol, 1,2-propanediol, 1,2-butanediol, 1,4-butanediol and water.

The binder is one or more of polyvinylpyrrolidone (PVP), polyvinyl alcohol (PVA), polyvinyl butyral (PVB), polyurethane, hydroxymethyl cellulose and ethyl cellulose.

The dispersant is one or more of methyl amyl alcohol, cellulose derivatives, polyacrylamide and polyethylene glycol fatty acid.

The leveling agent is one or more of sodium dodecyl sulfate, sodium dodecyl benzene sulfonate, sodium tetradecyl sulfonate, sodium hexadecyl sulfonate, lecithin, triethanolamine, KH550, polyethylene glycol, triethanolamine, Tween 80 and Span 80.

The tackifier is high-viscosity resin, and the high-viscosity resin is one or more of natural rubber, styrene-butadiene rubber, neoprene, and C5 and C9 petroleum resins.

The antioxidant is one or more of citric acid, phytic acid, vitamins, oxalic acid, ascorbic acid and glucose.

Preferably, the mass fraction of the solvent is 5%-40% of the mixture of the copper powder and the high molecular polymer, the mass fraction of the binder is 0.1%-15% of the mixture of the copper powder and the high molecular polymer, the mass fraction of the dispersant is 0.01%-2% of the mixture of the copper powder and the high molecular polymer, the mass fraction of the leveling agent is 0.01%-4% of the mixture of the copper powder and the high molecular polymer, the mass fraction of the tackifier is 0.01%-2% of the mixture of the copper powder and the high molecular polymer, and the mass fraction of the antioxidant is 0.01%-5% of the mixture of the copper powder and the high molecular polymer.

The copper powder is defined in such a way that a high structural strength of the copper paste is effectively ensured even with an ultra-thin thickness. The high molecular polymer is defined in such a way that the copper paste can form a uniform capillary structure after coating and sintering. The binding agent and the tackifier are defined as a binding phase of the system, which can keep the copper paste at a certain viscosity and prevent the copper powder from settling. The dispersant is defined in such a way that the copper powder and the high molecular polymer in different sizes can be evenly distributed to prevent caking. The leveling agent is defined in such a way that a uniform thickness can be maintained during coating of the copper paste. The antioxidant is defined in such a way that the copper paste is prevented from deteriorating due to oxidation reactions during storage.

The copper paste for printing a capillary structure is called copper paste for short. The principle is that the high molecular polymer with a microsphere particle size of 1-50 μm and the solvent which does not have dissolution or swelling reaction with the high molecular polymer are adopted; after coating, the high molecular polymer is evenly dispersed around the copper powder, occupying the space, and a porous copper layer structure is formed after binder removal; and adhesion occurs after copper particle sintering, and collapse occurs under the action of gravity, thus forming a porous copper layer structure with a certain structural strength.

According to the general idea for preparing a copper paste for capillary printing, the porosity of the copper paste is limited to about 50% due to the theoretical shrinkage of a copper oxide after reduction, while according to the design idea of this embodiment, the porosity of the copper paste can reach 60%-70%. Another notable feature is that the high molecular polymer with different microsphere particle size ranges can form different pore morphologies, featuring few closed pores, many open pores and three-dimensional continuous distribution, so when the copper paste is applied to a water absorption layer of a wick, the high porosity and multiple open pores allow the capillary force to be effectively and quickly utilized.

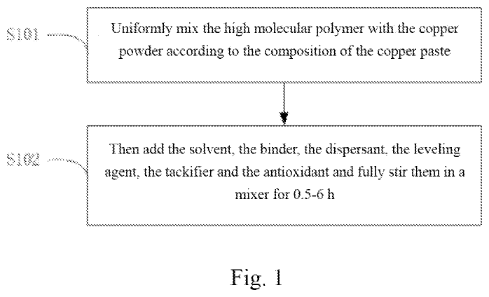

As shown in FIG. 1, a preparation method of the copper paste for printing a capillary structure comprises the following steps:
S101, uniformly mixing the high molecular polymer with the copper powder according to the composition of the copper paste; and
S102, then adding the solvent, the binder, the dispersant, the leveling agent, the tackifier and the antioxidant and fully stirring them in a mixer for 0.5-6 h.

A coating method of the copper paste composed of the raw constituents comprises the following steps: applying the copper paste on a carrier of a vapor chamber by blade coating or screen printing; then loading a coated sample on ceramics or quartz glass, and conducting binder removal at 400-600° C. in a nitrogen atmosphere; and finally sintering the sample after binder removal at a high temperature in a sintering furnace in the atmosphere of hydrogen or hydrogen-nitrogen mixed gas, and taking a porous copper layer finally obtained as a wick of the vapor chamber.

One-time coating or multiple-time coating can be adopted as needed to control the coating thickness, that is, the structure and size design of different wicks of the vapor chamber can be flexibly realized.

During binder removal, a large amount of waste gas can be generated, so a tail gas absorption device is needed; and in order to ensure gas flow in the binder removal process, nitrogen gas in large flow is needed. Binder removal can be conducted in a binder removal furnace or directly in the sintering furnace so as to reduce the use cost of equipment. In order to ensure the uniformity of the porous copper layer, thermal decomposition of other components than the copper powder needs to be controlled at the same temperature range.

In the step of sintering, the sintering temperature is 700-900° C., preferably 800-850° C., and the sintering time is 0.5-24 h, preferably 2-12 h. In order to control the balance between the porosity and structure of the porous copper layer, the sintering temperature can be set to less than 850° C. and the sintering time can be set to less than 2 h.

Compared with the related art, the copper paste for printing a capillary structure in the embodiment adopts the copper powder, the high molecular polymer, the solvent, the binder, the dispersant, the leveling agent, the tackifier and the antioxidant as raw constituents, and defines the particle size range of the copper powder and the particle size range of the microspheres of the high molecular polymer, so that the prepared copper paste can be applied to a carrier of a vapor chamber by blade coating or screen printing, and then used as a wick after binder removal and sintering in hydrogen or hydrogen-nitrogen mixed gas; and the thickness of the wick can be accurately controlled to be 10-100 μm, so as to meet the demand for miniaturization of electronic products, and the viscosity is 10000-35000 cps.

In addition, the copper paste for printing a capillary structure can adjust the parameters such as porosity and pore passage morphology of products at any time according to actual needs, and the sintering thickness, water absorption rate, structural strength and other performance indexes are better than those of copper mesh, composite copper mesh and copper oxide printing copper pastes. When the copper paste for printing a capillary structure is applied, full-automatic blade coating or screen printing equipment can be used, and by matching with a tunnel furnace, the preparation of the porous copper layer can be completed at high throughput; the steps of binder removal and sintering can be both completed in the sintering furnace, thus reducing the investment of equipment; after being stored for a long time, the copper paste for printing a capillary structure can be used simply by stirring, which improves the convenience of use; the copper paste for printing a capillary structure also has a three-dimensional interconnected open space structure with a pore size of 1-30 μm and a porosity of about 50%-70%; and the copper paste for printing a capillary structure can form channels with different pore passages due to the existence of the high molecular polymer with different microsphere particle sizes, thereby reducing the occurrence of closure of a single small pore passage due to the collapse of the copper powder in the sintering process.

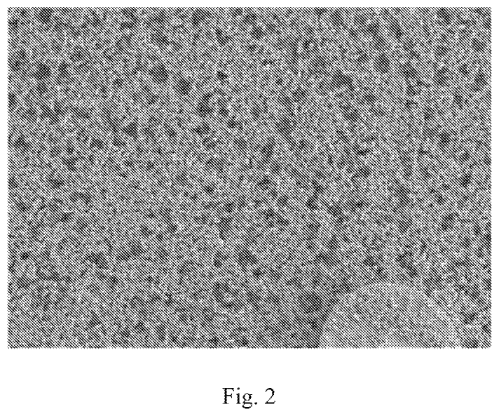

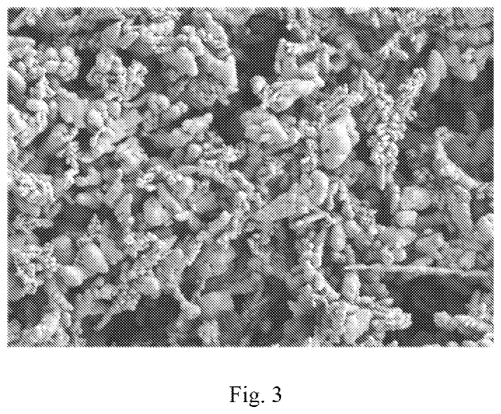

As shown in FIGS. 2 and 3, when the high molecular polymer is used as a component of the copper paste, after the copper paste is applied to the carrier of the vapor chamber to form the wick, pits with different sizes are formed in a surface of the wick, the sizes and density of the pits can be adjusted according to the particle size and usage amount of the microspheres of the high molecular polymer, and copper powder with small particle sizes is preferentially clustered together instead of being preferentially blended with large particles, which leads to a huge specific surface area; as a result, the capillary diameter is smaller, which leads to an excellent capillary force and an extremely high water absorption rate.

In order to better understand the specific steps of applying the copper paste for printing a capillary structure on the carrier of the vapor chamber in the present invention, explanation will be made below with ten more specific embodiments. The following components all correspond to the limits and ranges of the above components.

### Embodiment 1

Electrolytic copper powder with an average particle size of 10 μm and polymethyl methacrylate microspheres (PMMA microspheres) with a particle size of 3000 meshes were mixed according to the mass ratio of 8:1, the mixed powder was added to a PVB-ethylene glycol solution of which the mass fraction was 10% of the mixed powder, the mixture was fully stirred in a mixer, then a tackifier of which the mass fraction was 0.5% of the mixed powder, a dispersant of which the mass fraction was 0.5% of the mixed powder, an antioxidant of which the mass fraction was 1% of the mixed powder and other components of the copper paste described above were added in turn, and then stirring was conducted for 0.5-6 h.

Then, the mixed copper paste was applied to a VC sample (a carrier of a vapor chamber) through blade coating, then the VC sample was baked in an oven at 90-100° C. for 20 min and then put in a sintering furnace after the solvent was dried, N2 (nitrogen) was first introduced and binder removal was conducted at 450° C. for 90 min, and then N2/H2 (hydrogen) was introduced and sintering was conducted at 700-800° C. for 120 min to finally obtain a VC sample with a porous capillary structure.

### Embodiment 2

Electrolytic copper powder with an average particle size of 5 μm and polyisobutyl methacrylate microspheres (PiBMA microspheres) with a particle size of 3000 meshes were mixed according to the mass ratio of 9:1, the mixed powder was added to a PVP-1,2 propylene glycol solution of which the mass fraction was 8% of the mixed powder, the mixture was fully stirred in a mixer, then a tackifier of which the mass fraction was 0.5% of the mixed powder, a dispersant of which the mass fraction was 0.5% of the mixed powder, an antioxidant of which the mass fraction was 1% of the mixed powder and other components of the copper paste described above were added in turn, and then stirring was conducted for 0.5-6 h.

Then, the mixed copper paste was applied to a VC sample through blade coating, then the VC sample was baked in an oven at 90-100° C. for 30 min and then put in a sintering furnace after the solvent was dried, N2 was first introduced and binder removal was conducted at 450° C. for 120 min, and then N2/H2 was introduced and sintering was conducted at 800-850° C. for 120 min to finally obtain a VC sample with a porous capillary structure.

### Embodiment 3

Polymethyl methacrylate microspheres with a particle size of 500 meshes and polyoxymethylene microspheres (POM microspheres) with a particle size of 3000 meshes were mixed according to the mass ratio of 3:1 to form composite powder, electrolytic copper powder with an average particle size of 5 μm was mixed with the composite powder according to the mass ratio of 8:1, the mixed powder was added to a vinyl cellulose-1,2-propanediol solution of which the mass fraction was 10% of the mixed powder, the mixture was fully stirred in a mixer, then a tackifier of which the mass fraction was 0.5% of the mixed powder, a dispersant of which the mass fraction was 0.5% of the mixed powder, an antioxidant of which the mass fraction was 1% of the mixed powder and other components of the copper paste described above were added in turn, and then stirring was conducted for 0.5-6 h.

Then, the mixed copper paste was applied to a VC sample through blade coating, then the VC sample was baked in an oven at 90-100° C. for 20 min and then put in a sintering furnace after the solvent was dried, N2 was first introduced and binder removal was conducted at 500° C. for 90 min, and then N2/H2 was introduced and sintering was conducted at 700-800° C. for 120 min to finally obtain a VC sample with a porous capillary structure.

### Embodiment 4

Polymethyl methacrylate microspheres with particle sizes of 500 meshes and 3000 meshes were mixed according to the mass ratio of 4:1 to form composite powder, electrolytic copper powder with an average particle size of 3 μm was mixed with the composite powder according to the mass ratio of 8:1, the mixed powder was added to a vinyl cellulose-1,2-propanediol and ethylene glycol (volume ratio being 4:1) mixed solution of which the mass fraction was 10% of the mixed powder, the mixture was fully stirred in a mixer, then a tackifier of which the mass fraction was 0.5% of the mixed powder, a dispersant of which the mass fraction was 0.5% of the mixed powder, an antioxidant of which the mass fraction was 1% of the mixed powder and other components of the copper paste described above were added in turn, and then stirring was conducted for 0.5-6 h.

Then, the mixed copper paste was applied to a VC sample through blade coating, then the VC sample was baked in an oven at 90-100° C. for 30 min and then put in a sintering furnace after the solvent was dried, N2 was first introduced and binder removal was conducted at 450° C. for 90 min, and then N2/H2 was introduced and sintering was conducted at 700-800° C. for 120 min to finally obtain a VC sample with a porous capillary structure.

### Example 5

Electrolytic copper powder with an average particle size of 10 μm and polymethyl methacrylate microspheres with a particle size of 1000 meshes were mixed according to the mass ratio of 8:1, the mixed powder was added to a PVP-1,2 propylene glycol solution of which the mass fraction was 15% of the mixed powder, the mixture was fully stirred in a mixer, then a tackifier of which the mass fraction was 0.5% of the mixed powder, a dispersant of which the mass fraction was 0.5% of the mixed powder, an antioxidant of which the mass fraction was 1% of the mixed powder and other components of the copper paste described above were added in turn, and then stirring was conducted for 0.5-6 h.

Then, the mixed copper paste was applied to a VC sample through blade coating, then the VC sample was baked in an oven at 90-100° C. for 20 min and then put in a sintering furnace after the solvent was dried, N2 (nitrogen) was first introduced and binder removal was conducted at 450° C. for 90 min, and then N2/H2 was introduced and sintering was conducted at 700-800° C. for 120 min to finally obtain a VC sample with a porous capillary structure.

### Embodiment 6

Electrolytic copper powder with an average particle size of 10 μm and polyisobutyl methacrylate microspheres with a particle size of 1000 meshes were mixed according to the mass ratio of 8:1, the mixed powder was added to a PVP-1,2 propylene glycol solution of which the mass fraction was 15% of the mixed powder, the mixture was fully stirred in a mixer, then a tackifier of which the mass fraction was 0.5% of the mixed powder, a dispersant of which the mass fraction was 0.5% of the mixed powder, an antioxidant of which the mass fraction was 1% of the mixed powder and other components of the copper paste described above were added in turn, and then stirring was conducted for 0.5-6 h.

Then, the mixed copper paste was applied to a VC sample through blade coating, then the VC sample was baked in an oven at 90-100° C. for 20 min and then put in a sintering furnace after the solvent was dried, N2 (nitrogen) was first introduced and binder removal was conducted at 450° C. for 90 min, and then N2/H2 was introduced and sintering was conducted at 700-800° C. for 120 min to finally obtain a VC sample with a porous capillary structure.

### Embodiment 7

Electrolytic copper powder with an average particle size of 10 μm and polyformaldehyde microspheres (POM microspheres) with a particle size of 1000 meshes were mixed according to the mass ratio of 7:1, the mixed powder was added to a PVB-ethylene glycol and isobutanol (volume ratio being 5:1) mixed solution of which the mass fraction was 15% of the mixed powder, the mixture was fully stirred in a mixer, then a tackifier of which the mass fraction was 0.5% of the mixed powder, a dispersant of which the mass fraction was 0.5% of the mixed powder, an antioxidant of which the mass fraction was 1% of the mixed powder and other components of the copper paste described above were added in turn, and then stirring was conducted for 0.5-6 h.

Then, the mixed copper paste was applied to a VC sample through blade coating, then the VC sample was baked in an oven at 90-100° C. for 20 min and then put in a sintering furnace after the solvent was dried, N2 (nitrogen) was first introduced and binder removal was conducted at 500° C. for 90 min, and then N2/H2 was introduced and sintering was conducted at 800-850° C. for 120 min to finally obtain a VC sample with a porous capillary structure.

### Embodiment 8

Polymethyl methacrylate microspheres with particle sizes of 500, 2000 meshes and 8000 meshes were mixed according to the mass ratio of 4:1:1 to form composite powder, electrolytic copper powder with an average particle size of 3 μm was mixed with the composite powder according to the mass ratio of 7:1, the mixed powder was added to a vinyl cellulose-1,2-butanediol and ethylene glycol (volume ratio being 4:1) mixed solution of which the mass fraction was 6% of the mixed powder, the mixture was fully stirred in a mixer, then a tackifier of which the mass fraction was 0.5% of the mixed powder, a dispersant of which the mass fraction was 0.5% of the mixed powder, an antioxidant of which the mass fraction was 1% of the mixed powder and other components of the copper paste described above were added in turn, and then stirring was conducted for 0.5-6 h.

Then, the mixed copper paste was applied to a VC sample through blade coating, then the VC sample was baked in an oven at 90-110° C. for 30 min and then put in a sintering furnace after the solvent was dried, N2 was first introduced and binder removal was conducted at 450° C. for 90 min, and then N2/H2 was introduced and sintering was conducted at 700-800° C. for 120 min to finally obtain a VC sample with a porous capillary structure.

### Embodiment 9

Polymethyl methacrylate microspheres with particle sizes of 300 meshes, 2000 meshes and 8000 meshes were mixed according to the mass ratio of 4:1:1 to form composite powder, electrolytic copper powder with an average particle size of 3 μm was mixed with the composite powder according to the mass ratio of 7:1, the mixed powder was added to a vinyl cellulose-1,2-butanediol and 1,2-propanediol (volume ratio being 1:1) mixed solution of which the mass fraction was 10% of the mixed powder, the mixture was fully stirred in a mixer, then a tackifier of which the mass fraction was 0.5% of the mixed powder, a dispersant of which the mass fraction was 0.5% of the mixed powder, an antioxidant of which the mass fraction was 1% of the mixed powder and other components of the copper paste described above were added in turn, and then stirring was conducted for 0.5-6 h.

Then, the mixed copper paste was applied to a VC sample through blade coating, then the VC sample was baked in an oven at 90-110° C. for 30 min and then put in a sintering furnace after the solvent was dried, N2 was first introduced and binder removal was conducted at 450° C. for 90 min, and then N2/H2 was introduced and sintering was conducted at 700-800° C. for 120 min to finally obtain a VC sample with a porous capillary structure.

### Embodiment 10

Polymethyl methacrylate microspheres with particle sizes of 300, 3000 meshes and 12000 meshes were mixed according to the mass ratio of 4:2:1 to form composite powder, electrolytic copper powder with an average particle size of 3 μm was mixed with the composite powder according to the mass ratio of 8:1, the mixed powder was added to a polyvinyl alcohol-1,2-butanediol and isobutanol (volume ratio being 5:1) mixed solution of which the mass fraction was 8% of the mixed powder, the mixture was fully stirred in a mixer, then a tackifier of which the mass fraction was 0.5% of the mixed powder, a dispersant of which the mass fraction was 0.5% of the mixed powder, an antioxidant of which the mass fraction was 1% of the mixed powder and other components of the copper paste described above were added in turn, and then stirring was conducted for 0.5-6 h.

Then, the mixed copper paste was applied to a VC sample through blade coating, then the VC sample was baked in an oven at 90-110° C. for 30 min and then put in a sintering furnace after the solvent was dried, N2 was first introduced and binder removal was conducted at 450° C. for 90 min, and then N2/H2 was introduced and sintering was conducted at 700-800° C. for 120 min to finally obtain a VC sample with a porous capillary structure.

The above are only embodiments of the present invention, which do not limit the patent scope of the present invention. Any equivalent structure or equivalent flow transformation made by using the contents of the specification and drawings of the present invention, or directly or indirectly applied to other related technical fields, are equally included in the patent protection scope of the present invention.

What is claimed is:

1. A copper paste for printing a capillary structure, consisting of copper powder, a high molecular polymer, a solvent, a binder, a dispersant, a leveling agent, a tackifier and an antioxidant, wherein the particle size of the copper powder ranges from 0.5 μm to 10 μm, and the particle size of microspheres of the high molecular polymer ranges from 1 μm to 50 μm.

2. The copper paste for printing a capillary structure according to claim 1, wherein the particle size of the microspheres of the high molecular polymer is one or more of 300-1000 meshes, 1000-3000 meshes and 5000-12000 meshes, and the porosity of the high molecular polymer is 35%-75%.

3. The copper paste for printing a capillary structure according to claim 1, wherein the high molecular polymer is one or more of polymethyl methacrylate, polyisobutyl methacrylate, methyl methacrylate-isobutyl methacrylate copolymer, polyoxymethylene, polyurethane and polystyrene.

4. The copper paste for printing a capillary structure according to claim 1, wherein the solvent is one or more of ethanol, propanol, isopropanol, n-butanol, ethylene glycol, 1,2-propanediol, 1,2-butanediol, 1,4-butanediol and water.

5. The copper paste for printing a capillary structure according to claim 1, wherein the binder is one or more of polyvinylpyrrolidone (PVP), polyvinyl alcohol (PVA), polyvinyl butyral (PVB), polyurethane, hydroxymethyl cellulose and ethyl cellulose.

6. The copper paste for printing a capillary structure according to claim 1, wherein the dispersant is one or more of methyl amyl alcohol, cellulose derivatives, polyacrylamide and polyethylene glycol fatty acid.

7. The copper paste for printing a capillary structure according to claim 1, wherein the leveling agent is one or more of sodium dodecyl sulfate, sodium dodecyl benzene sulfonate, sodium tetradecyl sulfonate, sodium hexadecyl sulfonate, lecithin, triethanolamine, KH550, polyethylene glycol, triethanolamine, Tween 80 and Span 80.

8. The copper paste for printing a capillary structure according to claim 1, wherein the tackifier is high-viscosity resin, and the high-viscosity resin is one or more of natural rubber, styrene-butadiene rubber, neoprene, and C5 and C9 petroleum resins.

9. The copper paste for printing a capillary structure according to claim 1, wherein the antioxidant is one or more of citric acid, phytic acid, vitamins, oxalic acid, ascorbic acid and glucose.

10. The copper paste for printing a capillary structure according to claim 1, wherein the mass ratio of the copper powder to the high molecular polymer is 8-9:1, the mass fraction of the solvent is 1%-70% of a mixture of the copper powder and the high molecular polymer, the mass fraction of the binder is 0.1%-30% of the mixture of the copper powder and the high molecular polymer, the mass fraction of the dispersant is 0.01%-5% of the mixture of the copper powder and the high molecular polymer, the mass fraction of the leveling agent is 0.01%-10% of the mixture of the copper powder and the high molecular polymer, the mass fraction of the tackifier is 0.01%-5% of the mixture of the copper powder and the high molecular polymer, and the mass fraction of the antioxidant is 0.01%-10% of the mixture of the copper powder and the high molecular polymer.

11. The copper paste for printing a capillary structure according to claim 1, wherein the average particle size of the copper powder is 3 μm.

12. A preparation method of the copper paste for printing a capillary structure according to claim 1, comprising the following steps:
uniformly mixing the high molecular polymer with the copper powder according to the composition of the copper paste; and
then adding the solvent, the binder, the dispersant, the leveling agent, the tackifier and the antioxidant and fully stirring them in a mixer for 0.5-6 h.
